(19) United States
(12) Patent Application Publication
(10) Pub. No.: US 2026/0344338 A1
(43) Pub. Date: Oct. 29, 2026

(54) SUBSTRATE PROCESSING APPARATUS, MAINTENANCE METHOD, SUBSTRATE PROCESSING METHOD AND METHOD OF MANUFACTURING SEMICONDUCTOR DEVICE

(71) Applicant: Kokusai Electric Corporation, Tokyo (JP)

(72) Inventors: Toshiki FUJINO, Toyama (JP); Yuta KAWANISHI, Toyama (JP); Takeshi KASAI, Toyama (JP); Keisuke SAKASHITA, Toyama (JP)

(21) Appl. No.: 19/637,762

(22) Filed: Apr. 2, 2026

(30) Foreign Application Priority Data
Apr. 25, 2025 (JP) 2025-073396

(51) Int. Cl. H10P 72/00

(52) U.S. Cl. CPC H10P 72/0462

(57) ABSTRACT

It is possible to facilitate physical access to a rear portion of a substrate processing apparatus to improve its maintainability. There is provided a technique that includes: a process module including: a furnace structure provided with a process vessel for accommodating substrates therein; and a loading structure where the substrates are loaded into and unloaded from the process vessel, wherein the loading structure is provided below the furnace structure; a first utility system connected to one side surface of a rear portion of the process module and extending in height and depth directions; a second utility system connected to the other side surface of the rear portion of the process module and extending in the height and the depth direction; and a footboard provided between the first and the second utility system, wherein a maintenance space physically accessible to a person is formed below and above the footboard.

### CROSS REFERENCE TO RELATED APPLICATIONS

This non-provisional U.S. patent application is based on and claims priority under 35 U.S.C. § 119(a)-(d) to Japanese Patent Application No. 2025-073396, filed on Apr. 25, 2025, in the Japanese Patent Office, the entire contents of which are hereby incorporated by reference.

### TECHNICAL FIELD

The present disclosure relates to a substrate processing apparatus, a maintenance method, a substrate processing method and a method of manufacturing a semiconductor device.

### BACKGROUND

### Related Art

According to some related arts, a maintenance operation may be performed through a rear portion of a substrate processing apparatus.

### SUMMARY

According to the present disclosure, there is provided a technique capable of facilitating physical access to a rear portion of a substrate processing apparatus to improve a maintainability of the substrate processing apparatus.

According to an embodiment of the present disclosure, there is provided a technique that includes: a process module including: a furnace structure provided with a process vessel therein, wherein the process vessel is configured to be capable of accommodating a plurality of substrates therein; and a loading structure where the plurality of substrates are loaded into and unloaded from the process vessel, wherein the loading structure is provided below the furnace structure; a first utility system connected to one side surface of a rear portion of the process module and extending in a height direction and a depth direction; a second utility system connected to the other side surface of the rear portion of the process module and extending in the height direction and the depth direction; and a footboard provided between the first utility system and the second utility system, wherein a maintenance space physically accessible to a person is formed below and above the footboard.

### BRIEF DESCRIPTION OF THE DRAWINGS

FIG. 1 is a diagram schematically illustrating a perspective view of an example of a substrate processing apparatus according to one or more embodiments of the present disclosure.

FIG. 2 is a diagram schematically illustrating a perspective view of a rear portion of the substrate processing apparatus according to the embodiments of the present disclosure.

FIG. 3 is a diagram schematically illustrating a side view of a region (area) around a footboard installed on the rear portion of the substrate processing apparatus according to the embodiments of the present disclosure.

FIG. 4 is a diagram schematically illustrating a state when a maintenance operation is performed through the rear portion of the substrate processing apparatus according to the embodiments of the present disclosure.

FIG. 5 is a flow chart schematically illustrating a substrate processing according to the embodiments of the present disclosure.

FIG. 6 is a diagram schematically illustrating a perspective view of a rear portion of the substrate processing apparatus according to a modified example.

### DETAILED DESCRIPTION

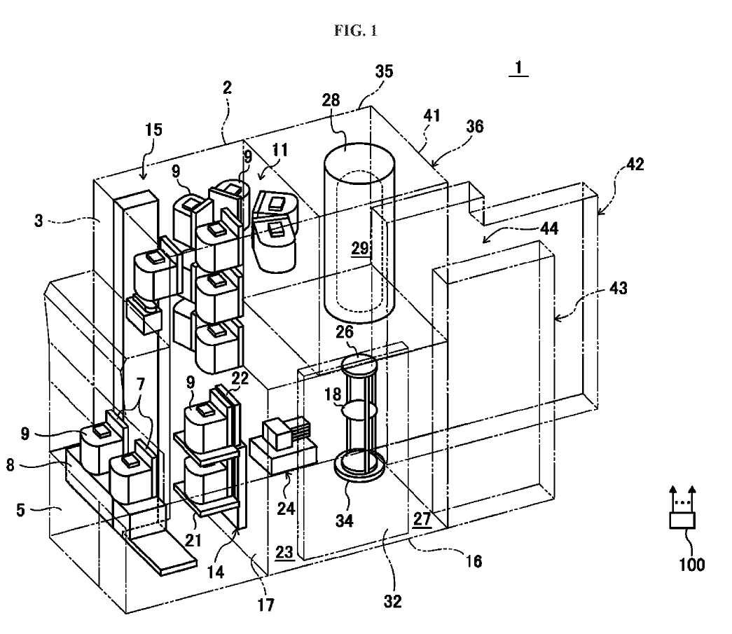

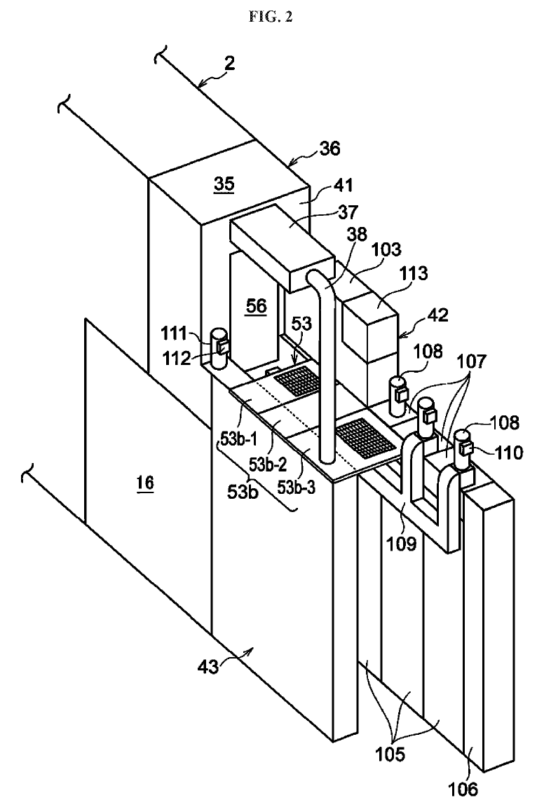

Hereinafter, one or more embodiments (also simply referred to as “embodiments”) according to the technique of the present disclosure will be described mainly with reference to FIGS. 1-6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, components substantially the same as those described with reference to FIGS. 1 and 2 are indicated by the same reference numerals, and redundant descriptions related thereto will be omitted. Further, the number of each component described in the present specification is not limited to one, and the number of each component may be two or more unless otherwise specified in the present specification. In addition, the technique of the present disclosure is not limited to the embodiments described below. That is, the technique of the present disclosure may be appropriately modified in various ways without departing from the scope thereof.

Further, in the following description, the term “worker” (or operator) refers to a person who performs a maintenance operation of a substrate processing apparatus 1 or a person who processes a substrate using the substrate processing apparatus 1. In addition, the maintenance operation may also be referred to as a “maintenance and inspection operation.” For example, the maintenance operation may be an operation (such as an inspection operation, a cleaning operation, a repair operation and a replacement operation) performed to maintain the substrate processing apparatus 1 in a normal state.

First, with reference to FIGS. 1-3, an outline of the substrate processing apparatus 1 according to the present embodiments will be described.

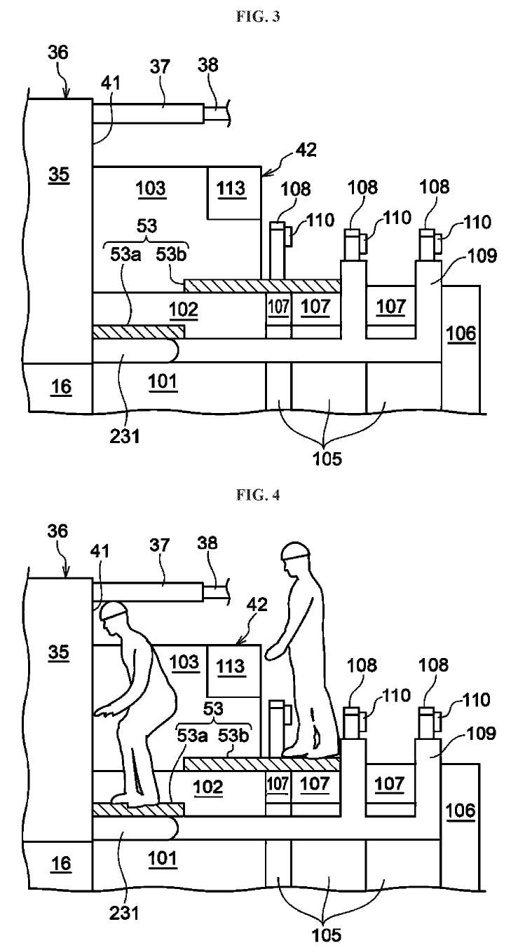

FIG. 1 is a diagram schematically illustrating a perspective view of an example of the substrate processing apparatus 1 according to the present embodiments. FIG. 2 is a diagram schematically illustrating a perspective view of a rear portion of the substrate processing apparatus 1 according to the present embodiments. In FIGS. 1 and 2, a vertical type substrate processing apparatus is shown as an example of the substrate processing apparatus 1. FIG. 3 is a diagram schematically illustrating a side view of a region (area) around a footboard 53 installed on the rear portion of the substrate processing apparatus 1.

As shown in FIGS. 1 and 2, the substrate processing apparatus 1 includes a housing 2. An opening for maintenance is provided at a lower portion of a front wall 3 of the housing 2. The opening can be opened or closed by a front maintenance door 5.

A pod loading/unloading port is provided at the front wall 3 of the housing 2 so as to communicate between an inside (inner portion) and an outside (outer portion) of the housing 2. The pod loading/unloading port can be opened or closed by a front shutter 7. A loading port (which is a loading port shelf) 8 is provided in front of the pod loading/unloading port. The loading port 8 is configured such that a pod 9 is aligned while placed on the loading port 8.

For example, the pod 9 is configured as a sealed type substrate transfer container. The pod 9 can be transferred (loaded) into and placed on the loading port 8 by an in-process transfer apparatus (not shown) and can be transferred (unloaded) out of the loading port 8 by the in-process transfer apparatus.

A rotatable pod shelf 11 is provided in the housing 2 to be located over a substantially center portion of the housing 2 in a front-rear direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”.

A pod opener 14 is provided below the rotatable pod shelf 11. The pod opener 14 is provided with a configuration on which the pod 9 is placed and capable of opening and closing a lid of the pod 9.

A pod transfer structure 15 is provided among the loading port 8, the rotatable pod shelf 11 and the pod opener 14. The pod transfer structure 15 is configured such that the pod 9 can be elevated and lowered and can be moved forward and backward in a horizontal direction while being supported by the pod transfer structure 15. The pod transfer structure 15 is further configured such that the pod 9 can be transferred among the loading port 8, the rotatable pod shelf 11 and the pod opener 14.

A sub-housing 16 is provided below the substantially center portion of the housing 2 in the front-rear direction to extend toward a rear end of the substrate processing apparatus 1. The sub-housing 16 serves as a loading structure where a wafer 18 can be transferred (or loaded) into and transferred (or unloaded) from/to a process furnace 28 described later. A pair of wafer loading/unloading ports through which the wafer 18 serving as a substrate is loaded into or unloaded out of the sub-housing 16 is provided at a front wall 17 of the sub-housing 16. The pair of wafer loading/unloading ports are arranged vertically in two stages. A pair of pod openers (including the pod opener 14) are provided at the pair of wafer loading/unloading ports, respectively. For example, an upper pod opener and a lower pod opener may be provided as the pair of pod openers. The upper pod opener and the lower pod opener may be collectively or individually referred to as the “pod opener 14”.

The pod opener 14 may include: a mounting table (which is a placement table) 21 where the pod 9 is placed thereon; and an opening/closing structure 22 capable of attaching and detaching the lid of the pod 9. The pod opener 14 is configured such that a wafer entrance of the pod 9 is opened or closed by opening (or detaching) or closing (or attaching) the lid of the pod 9 placed on the mounting table 21 by the opening/closing structure 22.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure 24 is provided at a front region of the transfer chamber 23. The wafer transfer structure 24 is configured such that the wafer 18 can be loaded into or unloaded out of a boat 26 serving as a substrate retainer. In a rear region of the transfer chamber 23, a standby space 27 where the boat 26 is accommodated and in standby is provided.

A sub-housing 35 is provided above the sub-housing 16 in the housing 2 to extend toward the rear end of the substrate processing apparatus 1. The sub-housing 35 serves as a furnace structure provided with the process furnace 28 capable of accommodating a plurality of wafers including the wafer 18. Hereinafter, the plurality of wafers including the wafer 18 may also be simply referred to as “wafers 18”. The process furnace 28 such as a vertical type process furnace is provided in the sub-housing 35 above the standby space 27. A process chamber 29 is provided inside the process furnace 28, and a lower end portion of the process chamber 29 is configured as a furnace opening. The furnace opening is opened or closed by a furnace opening shutter. The process furnace 28 serves as an example of a process vessel in which the wafer 18 is processed.

That is, the sub-housing 16 is disposed (located) below the sub-housing 35. A process module 36 is constituted by the sub-housing 16 and the sub-housing 35.

A boat elevator 32 capable of elevating and lowering the boat 26 is provided below the process furnace 28. A seal cap 34 serving as a lid is horizontally attached to the boat elevator 32. The seal cap 34 is configured such that the boat 26 can be vertically supported by the seal cap 34, and such that the furnace opening can be airtightly closed by the seal cap 34 while the boat 26 is loaded into the process chamber 29.

The boat 26 is configured such that a plurality of wafers (for example, from 50 wafers to 125 wafers) including the wafer 18 are supported on the boat 26 in a horizontal orientation in a multistage manner with their centers aligned with one another. Further, in the present specification, a notation of a numerical range such as “from 50 wafers to 125 wafers” means that a lower limit and an upper limit are contained in the numerical range. Therefore, for example, a numerical range “from 50 wafers to 125 wafers” means a range equal to or higher than 50 wafers and equal to or less than 125 wafers. The same also applies to other numerical ranges described in the present specification.

A first utility system 42 and a second utility system 43 are provided at a rear wall 41 of the housing 2 on a rear portion of the process module 36 such that a side surface of the first utility system 42 and a side surface of the second utility system 43 are formed continuously with side surfaces of the housing 2, respectively. In other words, the first utility system 42 (which extends in a height direction and a depth direction) is connected to one side surface of the rear portion of the process module 36, and the second utility system 43 (which extends in the height direction and the depth direction) is connected to the other side surface of the rear portion of the process module 36. The first utility system 42 and the second utility system 43 are arranged opposite to each other.

A maintenance space 44 is provided (or formed) between the first utility system 42 and the second utility system 43. The maintenance space 44 is a space where a worker (operator) can perform the maintenance operation for the substrate processing apparatus 1.

The first utility system 42 includes a gas supplier (also referred to as a “gas supply structure”) configured to supply a gas into the process furnace 28. The second utility system 43 includes a gas exhauster (also referred to as a “gas exhaust structure”) configured to exhaust the gas from the process furnace 28.

An exhaust duct 37 through which the gas is exhausted from the process furnace 28 is connected to an upper portion of the rear wall 41. A pipe 38 in communication with an inside of the second utility system 43 is connected to the exhaust duct 37.

In addition, maintenance and inspection ports are provided at the rear wall 41 of the sub-housing 16 and the sub-housing 35, and doors 56 are provided at the maintenance and inspection ports, respectively. Each of the doors 56 is configured to be capable of being opened and closed with respect to the rear wall 41. Hereinafter, each of the doors 56 may also be simply referred to as a “door 56”.

For example, the first utility system 42 is configured such that a first gas box (not shown), a first electrical component box 101, a second gas box 102 and a second electrical component box 103 are stacked in the height direction (vertical direction) from a lower end toward an upper end of the rear wall 41. A plurality of extension gas boxes (which are elongated in the vertical direction) 105 are provided at a rear portion (that is, in the depth direction) of the first utility system 42 such that the extension gas boxes 105 are formed continuously with side surfaces of the first gas box, the first electrical component box 101, the second gas box 102 and the second electrical component box 103. In addition, a third electrical component box (which is elongated in the vertical direction) 106 is provided at rear portions of the extension gas boxes 105 such that the third electrical component box 106 is provided continuously with side surfaces of the extension gas boxes 105. A plurality of subsidiary electrical component boxes 107 are provided above the extension gas boxes 105, respectively. A gas detector 113 is also provided in a corner of the second electrical component box 103.

In the first gas box, the second gas box 102 and the extension gas boxes 105, for example, components such as various gas tanks, vaporizers, gas flow rate controllers, pipes and valves related thereto can be accommodated.

Corresponding to the extension gas boxes 105, a duct 109 accommodating a plurality of exhaust ducts 108 is provided on outer walls of the subsidiary electrical component boxes 107 so as to protrude toward the maintenance space 44. End portions of the exhaust ducts 108 are arranged on upper surfaces of the subsidiary electrical component boxes 107, respectively. In addition, a plurality of exhaust valves (also referred to as “exhaust dampers”) 110 are provided on side surfaces of the end portions of the exhaust ducts 108, respectively. Thereby, it is possible to prevent a gas leak into the subsidiary electrical component boxes 107. In addition to the exhaust ducts 108, the duct 109 also accommodates a pipe in communication with the process chamber 29.

In the first electrical component box 101 and the second electrical component box 103, for example, a control apparatus (control structure) configured to control the substrate processing apparatus 1 and an operation panel through which the worker performs an operation are accommodated. In the subsidiary electrical component boxes 107, for example, a control apparatus (control structure) configured to control a gas supply system accommodated in the extension gas boxes 105 is accommodated.

For example, an end portion of an exhaust duct 111 is arranged on an upper surface of the second utility system 43 in the vicinity of the rear wall 41. In addition, an exhaust valve 112 is provided on a side surface of the end portion of the exhaust duct 111.

For example, a side surface of the first utility system 42 adjacent to the maintenance space 44 is formed by a door or a panel of a flat shape, and constituted by a flat surface occupying more than half of the side surface of the first utility system 42 and a protrusion (such as the duct 109) protruding from the flat surface toward the maintenance space 44.

For example, the footboard 53 is provided between the first utility system 42 and the second utility system 43. In addition, above and below the footboard 53, the maintenance space 44 physically accessible to a person (that is, the worker) is provided (or formed).

The maintenance space 44 is provided in the entire region (area) immediately below the footboard 53. The maintenance space 44 formed below the footboard 53 is configured to make it possible for the person (that is, the worker) to physically access to portions of the first utility system 42 and the second utility system 43 (which are below the footboard 53) and the sub-housing 16.

In addition, the maintenance space 44 formed above the footboard 53 is configured to make it possible for the person (that is, the worker) to physically access to portions of the first utility system 42 and the second utility system 43 (which are above the footboard 53) and the sub-housing 35.

The footboard 53 includes a first plate 53a provided close to the rear wall 41 and a second plate 53b provided farther from the rear wall 41 than the first plate 53a. Heights of the first plate 53a and the second plate 53b are set to be different from each other. Specifically, the first plate 53a of the footboard 53 is configured to be lower in the height direction than the second plate 53b.

The first plate 53a is located immediately above an exhaust pipe 231 protruding rearward from the rear wall 41 of the sub-housing 35. The second plate 53bis located in accordance with a height of the second utility system 43 (which is the lower among the first utility system 42 and the second utility system 43). For example, the second plate 53b is located at substantially the same height or at the same height as the second utility system 43. In addition, in a region where the protrusion (such as the duct 109) is located, the second plate 53b is located higher than the protrusion (such as the duct 109). In addition, a rear end of the footboard 53 is located in accordance with a rear end of the second utility system 43 (which is the shorter among the first utility system 42 and the second utility system 43), and is located at substantially the same position or at the same position as the rear end of the second utility system 43. Thereby, it is possible to reduce a footprint while ensuring the maintenance space 44.

In addition, the second plate 53b is configured to be removable in a plurality of portions, for example, three portions. Specifically, for example, the second plate 53b includes a first portion 53b-1, a second portion 53b-2 and a third portion 53b-3, each of which is configured to be removable. Therefore, by separating and removing a portion (among the first portion 53b-1, the second portion 53b-2 and the third portion 53b-3) of the second plate 53b above a specific portion of the first utility system 42 or the second utility system 43 from the other portions of the second plate 53b, the specific portion is physically accessible from above the maintenance space 44.

For example, the footboard 53 is made of a metal material, and at least a part of the second plate 53b is configured with a grating of a lattice shape. Thereby, it is possible to provide lighting for the maintenance space 44 below the footboard 53.

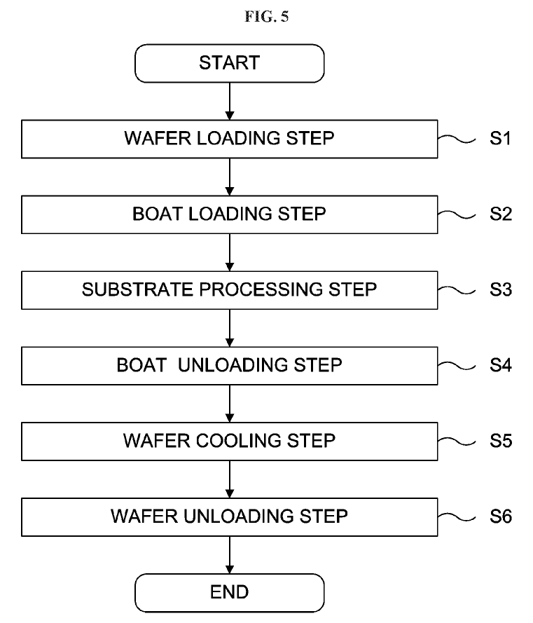

Subsequently, an action of the person (worker) performing the maintenance through the rear portion of the substrate processing apparatus 1 will be described with reference to FIGS. 3 and 4.

In the first utility system 42 above the footboard 53, components such as the second electrical component box 103, the gas detector 113, the exhaust ducts 108 and the exhaust valves 110 are provided. In addition, in the second utility system 43 above the footboard 53, components such as the exhaust duct 111 and the exhaust valve 112 are provided.

For example, the worker wears a safety harness, climbs onto the footboard 53 using a stepladder or ladder. Then, the worker can perform the maintenance operation on the first utility system 42 (for example, the components such as the second electrical component box 103, the gas detector 113, the exhaust ducts 108 and the exhaust valves 110) and the second utility system 43 (for example, the components such as the exhaust duct 111 and the exhaust valve 112), which are located higher than the footboard 53, in the maintenance space 44 above the footboard 53. In addition, the worker moves from above the second plate 53b to above the first plate 53a, and opens the door 56 (which is located higher than the first plate 53a) of the sub-housing 35. Then, the worker can perform the maintenance operation on a heater chamber.

Specifically, for example, the worker opens the door 56 of the heater chamber. Then, as the maintenance operation, the worker can check a tightening state of heater terminals, check an insulation resistance, check for a cooling water leak, or replace a component such as thermocouples. For example, the height of the first plate 53a may be set to the same height as a lower surface of the heater chamber such that the worker can replace a heater on the first plate 53a. In addition, the worker can open a door of the second electrical component box 103. Then, as the maintenance operation, the worker can perform an appropriate operation for the second electrical component box 103, check the gas detector 113, or perform appropriate operations for the exhaust ducts 108, the exhaust duct 111, the exhaust valves 110 and the exhaust valve 112.

Subsequently, a substrate processing using the substrate processing apparatus 1 prepared by performing the maintenance operation mentioned above will be described with reference to FIG. 5. In the following description, operations of components constituting the substrate processing apparatus 1 are controlled by a controller 100 serving as a control structure.

The substrate processing will be described by way of an example in which the wafer 18 is annealed in the process chamber 29, which is performed as a part of a manufacturing process of a semiconductor device. In the present specification, the term “process temperature” may refer to a “temperature of the wafer 18” or a “temperature (inner temperature) of the process chamber 29”, and the term “process pressure” may refer to a “pressure (inner pressure) of the process chamber 29”. In addition, the term “process time” may refer to a time duration of continuously performing a process related thereto. The same also applies to the following description.

First, in a step S1, the plurality of wafers 18 are loaded (that is, charged) into the boat 26 which is lowered outside the process chamber 29.

Subsequently, in a step S2, the boat 26 is elevated and loaded into the process chamber 29. Thereby, the wafers 18 are loaded (or accommodated) in the process chamber 29. A lower end opening of the process furnace 28 is then closed (that is, sealed) by the seal cap 34. Then, the process chamber 29 is vacuum-exhausted by a vacuum pump (not shown). In addition, while an inert gas is supplied through the gas supplier, the inner pressure of the process chamber 29 is adjusted to a predetermined pressure using an APC (Automatic Pressure Controller) valve (not shown). By adjusting an AC power applied to an induction coil based on temperature information detected by the thermocouples such that the temperature of the wafer 18 reaches and is maintained at a predetermined process temperature, the wafer 18 is heated to a predetermined temperature (process temperature) at a predetermined rate.

Subsequently, in a step S3, the wafer 18 is exposed to a predetermined atmosphere, a predetermined temperature (process temperature) and a predetermined pressure (process pressure) for a predetermined time. Thereby, it is possible to anneal the wafer 18 by activating impurities (which was ion-implanted into the wafer 18) or by removing oxygen from a surface of the wafer 18.

Subsequently, in a step S4, the temperature of the wafer 18 is lowered to a predetermined temperature by adjusting the power supplied to the induction coil, and the APC valve is closed to return the inner pressure of the process chamber 29 to an atmospheric pressure. Thereafter, the seal cap 34 is lowered, and the boat 26 is taken out (that is, unloaded) from the process furnace 28.

Subsequently, in a step S5, after the boat 26 is unloaded, the wafer 18 is further cooled until the temperature of the wafer 18 reaches a temperature at which the wafer 18 can be transferred.

Subsequently, in a step S6, the wafers (which is processed) 18 are unloaded from the boat 26 by the wafer transfer structure 24 and stored in the pod 9.

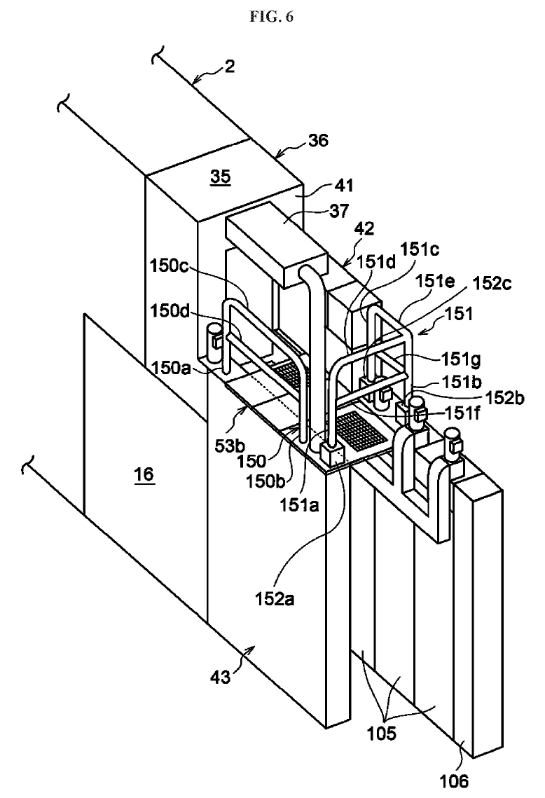

FIG. 6 is a diagram schematically illustrating a rear portion of the substrate processing apparatus 1, according to a modified example.

In FIG. 6, protective fences (also referred to as “handrails”) 150 and 151 of a cylindrical shape are provided to surround the footboard 53 on the rear portion of the substrate processing apparatus 1 shown in FIG. 2.

The protective fence 150 may include: two support columns 150a and 150b erected at a predetermined distance from each other on the upper surface of the second utility system 43; a first connector (first connecting structure) 150c connecting an upper end of the support column 150a to an upper end of the support column 150b; and a second connector (second connecting structure) 150d connecting a portion between the upper end and a lower end of the support column 150a to a portion between the upper end and a lower end of the support column 150b, substantially parallel to the first connector 150c.

The protective fence 151 may include: a support column 151a erected in the vicinity of a rear end portion of the upper surface of the second utility system 43; a support column 151b erected in the vicinity of a rear end portion of an upper surface of the first utility system 42; a support column 151c erected in front of the support column 151b on the upper surface of the first utility system 42; a first connector (first connecting structure) 151d connecting an upper end of the support column 151a to an upper end of the support column 151b; a second connector (second connecting structure) 151e connecting the upper end of the support column 151b to an upper end of the support column 151c; a third connector (third connecting structure) 151f connecting a portion between the upper end and a lower end of the support column 151a to a portion between the upper end and a lower end of the support column 151b, substantially parallel to the first connector 151d; and a fourth connector (fourth connecting structure) 151g connecting the portion between the upper end and the lower end of the support column 151b to a portion between the upper end and a lower end of the support column 151c, substantially parallel to the second connector 151e. In other words, the protective fence 151 is bent approximately vertically from above the rear end of the footboard 53 toward the first utility system 42.

In addition, the support column 151a is supported by a support structure 152a provided in the vicinity of the rear end portion of the upper surface of the second utility system 43. The support column 151b is supported by a support structure 152b provided in the vicinity of the rear end portion of the upper surface of the first utility system 42. The support column 151c is supported by a support structure 152c provided in front of the support structure 152b on the upper surface of the first utility system 42.

The support structure 152a is configured to be taller than the support structures 152b and 152c. Therefore, when the worker lifts the protective fence 151 upward, the support columns 151b and 151c are detached from the support structures 152b and 152c, while the support column 151a remains supported by the support structure 152a. Thereby, it is possible to open or close the protective fence 151 around the support columns 151a.

According to the present modified example, it is possible to obtain substantially the same effects as in the embodiments mentioned above. In addition, according to the present modified example, it is possible to further improve safety during the maintenance operation at a position higher than the footboard 53.

The configurations of the substrate processing apparatus 1 described in the embodiments and the modified example mentioned above are merely examples, and may be changed depending on the situation, without departing from the scope of the technique of the present disclosure.

Further, the process flow described in the embodiments mentioned above is merely an example, and a redundant step may be deleted, a new step may be added or process procedures may be changed, without departing from the scope of the technique of the present disclosure.

For example, the technique of the present disclosure may be applied to not only a substrate processing apparatus capable of manufacturing a semiconductor device but also an apparatus capable of processing a glass substrate, such as an LCD (Liquid Crystal Display) manufacturing apparatus, or other substrate processing apparatus. The contents of the substrate processing may include not only the annealing process but also a process such as a film forming process of forming a film (such as a CVD (Chemical Vapor Deposition) film, a PVD (Physical Vapor Deposition) film, an epitaxial growth film, an oxide film, a nitride film and a metal-containing film), an oxidation process, a diffusion process, an etching process, an exposure process, a photolithography process, a coating process, a molding process, a developing process, a dicing process, a wire bonding process and an inspection process.

For example, the embodiments mentioned above are described by way of an example in which the vertical type substrate processing apparatus (also referred to as a “batch type substrate processing apparatus”) capable of simultaneously processing a plurality of substrates is used to process the substrate. However, the technique of the present disclosure is not limited thereto. For example, the technique of the present disclosure may be preferably applied when a single wafer type substrate processing apparatus capable of simultaneously processing one or several substrates at a time is used to process the substrate. For example, the embodiments mentioned above are described by way of an example in which a substrate processing apparatus including a hot wall type process furnace is used to process the substrate. However, the technique of the present disclosure is not limited thereto. For example, the technique of the present disclosure may be preferably applied when a substrate processing apparatus including a cold wall type process furnace is used to process the substrate.

The process procedures and the process conditions of each process using the substrate processing apparatuses exemplified above may be substantially the same as those of the embodiments or the modified example described above. Even in such a case, it is possible to obtain substantially the same effects as in the embodiments or the modified example described above.

In addition, the embodiments and the modified example mentioned above may be appropriately combined. The process procedures and the process conditions of each combination thereof may be substantially the same as those of the embodiments mentioned above or the modified example mentioned above.

As described above, according to some embodiments of the present disclosure, it is possible to facilitate physical access to the rear portion of the substrate processing apparatus to improve a maintainability of the substrate processing apparatus.

What is claimed is:

1. A substrate processing apparatus comprising:
a process module comprising:
a furnace structure provided with a process vessel therein, wherein the process vessel is configured to be capable of accommodating a plurality of substrates therein; and
a loading structure where the plurality of substrates are loaded into and unloaded from the process vessel, wherein the loading structure is provided below the furnace structure;
a first utility system connected to one side surface of a rear portion of the process module and extending in a height direction and a depth direction;
a second utility system connected to the other side surface of the rear portion of the process module and extending in the height direction and the depth direction; and
a footboard provided between the first utility system and the second utility system, wherein a maintenance space physically accessible to a person is formed below and above the footboard.

2. The substrate processing apparatus of claim 1, wherein the maintenance space formed below the footboard is configured to make it possible for the person to physically access to the loading structure and a portion of at least one of the first utility system or the second utility system below the footboard.

3. The substrate processing apparatus of claim 1, wherein the maintenance space is provided in an entire region immediately below the footboard.

4. The substrate processing apparatus of claim 1, wherein the footboard comprises a first plate provided near the rear portion of the process module and a second plate provided farther from the rear portion of the process module than the first plate, and wherein heights of the first plate and the second plate are set to be different from each other.

5. The substrate processing apparatus of claim 4, wherein the first plate is configured to be lower than the second plate.

6. The substrate processing apparatus of claim 4, wherein the first plate is located immediately above an exhaust pipe protruding rearward from the rear portion of the process module.

7. The substrate processing apparatus of claim 4, wherein the second plate is located in accordance with a height of a lower one among the first utility system and the second utility system.

8. The substrate processing apparatus of claim 1, wherein the maintenance space formed above the footboard is configured to make it possible for the person to physically access to the furnace structure and a portion of at least one among the first utility system and the second utility system above the footboard.

9. The substrate processing apparatus of claim 8, wherein at least one of an electrical component box, a gas detector or an exhaust valve is provided in the first utility system and the second utility system above the footboard.

10. The substrate processing apparatus of claim 1, wherein a rear end of the footboard is located in accordance with a rear end of a shorter one among the first utility system and the second utility system.

11. The substrate processing apparatus of claim 1, wherein at least one among the first utility system or the second utility system is provided with a gas supply structure configured to supply a gas into the process vessel, and
wherein at least one of the first utility system or the second utility system is provided with a gas exhaust structure configured to exhaust the gas from the process vessel.

12. The substrate processing apparatus of claim 1, wherein a side surface of the first utility system adjacent to the maintenance space is constituted by a flat surface occupying more than half of the side surface of the first utility system and a protrusion protruding from the flat surface toward the maintenance space, and
wherein the footboard is located higher than the protrusion in a region where the protrusion is located.

13. The substrate processing apparatus of claim 1, wherein a portion of the footboard above a specific portion of the first utility system or the second utility system is capable of being separated and removed from other portions of the footboard such that the specific portion is physically accessible from above the maintenance space.

14. A maintenance method comprising:
(a) preparing a substrate processing apparatus comprising:
a process module comprising:
a furnace structure provided with a process vessel therein, wherein the process vessel is configured to be capable of accommodating a plurality of substrates therein; and
a loading structure where the plurality of substrates are loaded into and unloaded from the process vessel, wherein the loading structure is provided below the furnace structure;
a first utility system connected to one side surface of a rear portion of the process module and extending in a height direction and a depth direction; and
a second utility system connected to the other side surface of the rear portion of the process module and extending in the height direction and the depth direction; and
(b) performing a maintenance operation on at least one among the furnace structure, the first utility system and the second utility system, which are located higher than a footboard for a worker to stand on,
wherein the footboard is provided between the first utility system and the second utility system, and a maintenance space physically accessible to the worker is formed below and above the footboard.

15. A substrate processing method comprising:
(a) preparing a substrate processing apparatus comprising:
a process module comprising:
a furnace structure provided with a process vessel therein, wherein the process vessel is configured to be capable of accommodating a plurality of substrates therein; and
a loading structure where the plurality of substrates are loaded into and unloaded from the process vessel, wherein the loading structure is provided below the furnace structure;
a first utility system connected to one side surface of a rear portion of the process module and extending in a height direction and a depth direction;
a second utility system connected to the other side surface of the rear portion of the process module and extending in the height direction and the depth direction; and
a footboard provided between the first utility system and the second utility system, wherein a maintenance space physically accessible to a person is formed below and above the footboard; and
(b) placing the plurality of substrates in the process vessel, and processing the plurality of substrates in a predetermined atmosphere and at a predetermined temperature.

16. A method of manufacturing a semiconductor device, comprising:
the method of claim 15.
